(19) United States
(12) Patent Application Publication
(10) Pub. No.: US 2007/0221923 A1
(43) Pub. Date: Sep. 27, 2007

(54) Array substrate and method of manufacturing the same

(75) Inventors: Masaki Obi, Ageo-shi (JP); Hiroharu Inoue, Fukaya-shi (JP); Atsuyuki Manabe, Fukaya-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Toshiba Matsushita Display Technology Co., Ltd.

(21) Appl. No.: 11/723,442

(22) Filed: Mar. 20, 2007

(30) Foreign Application Priority Data
Mar. 24, 2006 (JP) 2006-083227

(51) Int. Cl. H01L 29/04

(52) U.S. Cl. 257/59

(57) ABSTRACT

A method of manufacturing an array substrate comprising forming a plurality of scanning lines, a plurality of signal lines and a plurality of switching elements on a substrate, forming an under layer having a plurality of color layers overlapping the scanning lines, the signal lines and the switching elements, a plurality of base parts, and a plurality of protective parts located near the base parts and having a height equal to or greater than that of the base parts, polishing a surface of the under layer, and forming a plurality of pillar-shaped spacers on the base parts after the surface of the under layer has been polished.

### CROSS-REFERENCE TO RELATED APPLICATIONS

This application is based upon and claims the benefit of priority from prior Japanese Patent Application No. 2006-083227, filed Mar. 24, 2006, the entire contents of which are incorporated herein by reference.

### BACKGROUND OF THE INVENTION

1. Field of the Invention

The present invention relates to an array substrate and a method of manufacturing an array substrate.

2. Description of the Related Art

Most liquid crystal display panels comprise an array substrate, a counter substrate, and a liquid crystal layer. The counter substrate is arranged opposite to the array substrate and spaced therefrom by a predetermined gap. The liquid crystal layer is interposed between these substrates. The array substrate has a glass substrate, a plurality of scanning lines, a plurality of signal lines, a plurality of thin-film transistors (TFTs), an under layer, a plurality of pixel electrodes, a plurality of pillar-shaped spacers, and an alignment film. The scanning lines, signal lines, TFTs and under layer are formed on the glass substrate. The pixel electrodes, spacers and alignment film are formed on the under layer. The under layer is constituted by color filters (color layers), i.e., red layers, green layers and blue layers that are arranged adjacent to one another.

The signal lines are arranged, intersecting with the scanning lines. Therefore, the signal lines and the scanning lines form a lattice. The TFTs are located at the intersections of the signal lines and scanning lines. The color layers are formed on the glass substrate, covering the signal lines, scanning lines and TFTs. The pixel electrodes are formed on the color layers, respectively, and have a prescribed shape. The pixel electrodes extend through the contact holes made in the color layers and are electrically connected to the TFTs. The pillar-shaped spacers have been formed on the bases of the color layers, by means of the application of resist, light exposure, development and post-baking. The spacers have a desired size and a desired height. The alignment film is formed on the color layers and pixel electrodes.

The counter substrate has a glass substrate, a counter electrode, and an alignment film. The counter electrode and the alignment film are laid on the glass substrate in the order they are mentioned.

The array substrate and the counter substrate are arranged opposite to each other with a predetermined gap therebetween by spaces. The array substrate and the counter substrate are bonded to each other with a sealing member provided in the edge portions of both substrates. The liquid crystal layer is provided in a space defined by the arrange substrate, counter electrode and the sealing member.

As in most cases, stepped parts having a height in the order of microns are formed in the color layers, at the positions where the signal lines and scanning lines overlap the TFTs. At the stepped parts of the color layers, alignment errors may occur, depending on the mode of the liquid crystal used. Alignment errors, if any, will decrease the image contrast of the liquid crystal display panel.

To improve the optical characteristics of the liquid crystal display panel, it is necessary to reduce the stepped parts of the color layers, i.e., swellings on the array substrate. That is, the stepped parts of the color layers must be rendered small. In view of this, it is proposed that the color layers be mechanically polished to make the surfaces of the color layers flat as is disclosed in Jpn. Pat. Appln. KOKAI Publication No. 9-230124. If the surface of every color layer is flat, the decrease in the image contrast due to the light dissipation will be suppressed.

To enhance the quality of images the liquid crystal display panel displays, the cell gap must be uniformed at high precision. If the color layers are mechanically polished, however, they will be polished to different degrees in the plane of the substrate. More precisely, the color layers at the peripheries of the substrate will be more polished than those at the center of the substrate. The difference is prominent, particularly between the stepped parts of the color layers. The cell gap in the liquid crystal display panel is determined mainly by the sum of the height of each stepped part (i.e., distance between the top and the base) and the height of each pillar-shaped spacer.

In view of the foregoing, the color layers are likely to have different heights (i.e., distance between the top and base) if the they are mechanically polished. Inevitably, the cell gap will not be uniform. In this case, the quality of images the liquid crystal display panel displays may decrease.

### BRIEF SUMMARY OF THE INVENTION

The present invention has been made in consideration of the above. An object of the invention is to provide an array substrate that helps to provide a liquid crystal display panel able to display high-quality images and a method of manufacturing this array substrate.

To achieve the object, in accordance with an aspect of the invention, there is provided a method of manufacturing an array substrate comprising:

forming a plurality of scanning lines, a plurality of signal lines and a plurality of switching elements on a substrate;

forming an under layer having a plurality of color layers overlapping the scanning lines, the signal lines and the switching elements, a plurality of base parts, and a plurality of protective parts located near the base parts and having a height equal to or greater than that of the base parts;

polishing a surface of the under layer; and

forming a plurality of pillar-shaped spacers on the base parts after the surface of the under layer has been polished.

In accordance with another aspect of the invention, there is provided an array substrate comprising:

a plurality of scanning lines, a plurality of signal lines and a plurality of switching elements which are formed on a substrate;

an under layer which has a plurality of color layers overlapping the scanning lines, the signal lines and the switching elements, a plurality of base parts, and a plurality of protective parts located near the base parts and having a height equal to or greater than that of the base parts; and

a plurality of pillar-shaped spacers formed on the base parts.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing a liquid crystal display panel manufactured by a method that includes a method of manufacturing an array substrate according to an embodiment of the present invention;

FIG. 2 is a plan view showing the array substrate, particularly color filters according to Embodiments 1 to 10 of the invention;

FIG. 3 is a magnified plan view showing the array substrate, schematically illustrating the array wiring section, the color filters and the pillar-shaped spacers;

FIG. 4 is a sectional view of the liquid crystal display panel;

FIG. 5 is a sectional view of the liquid crystal display panel, taken along line V-V shown in FIG. 3;

FIG. 6 is a sectional view of the liquid crystal display panel, taken along line VI-VI shown in FIG. 3;

FIG. 7 is a magnified plan view of the array substrate, particularly showing the relation between the protective portions and the pillar-shaped spacers;

FIG. 8 is a sectional view illustrating a step of manufacturing the array substrate and showing color layers formed;

FIG. 9 is a sectional view illustrating the step of manufacturing the array substrate and showing the color layers;

FIG. 10 is a perspective view schematically explaining a step of polishing the surfaces of the color layers shown in FIGS. 8 and 9 by a polishing apparatus during the manufacture of the array substrate;

FIG. 11 is a magnified plan view showing an array substrate manufactured by a method according to Embodiments 11 to 21 of this invention, schematically illustrating the array wiring section, the color filter and the pillar-shaped spacers;

FIG. 12 is a magnified plan view of the array substrate shown in FIG. 11, particularly illustrating the relation between the protective portions and the pillar-shaped spacers;

FIG. 13 is a magnified plan view of an array substrate made by a method according to Embodiment 22 of this invention, schematically showing the array wiring section, the color filter and the pillar-shaped spacers;

FIG. 14 is a magnified plan view of an array substrate made by a method according to Embodiment 23 of this invention, schematically depicting the array wiring section, the color filter and the pillar-shaped spacers;

FIG. 15 is a graph representing how the degree of polishing the base parts of the array substrate changes with the height thereof, measured from the plane of the color layers to the surface of the base parts;

FIG. 16 is a graph showing how the degree of polishing the base of the array substrate changes with the size of the first protective sections and the distance between the first protective portions opposing to each other across the base parts; and

FIG. 17 is a graph showing how the degree of polishing the base parts of the array substrate changes with the size of the second protective portions and the distance between the second protective portion and the base part.

### DETAILED DESCRIPTION OF THE INVENTION

An array substrate and a method of manufacturing an array substrate, both being embodiments of the present invention, will be described in detail with reference to the accompanying drawings, together with a liquid crystal display panel and a method of manufacturing a liquid crystal display. First, the configuration of the liquid crystal display panel made by this method will be described.

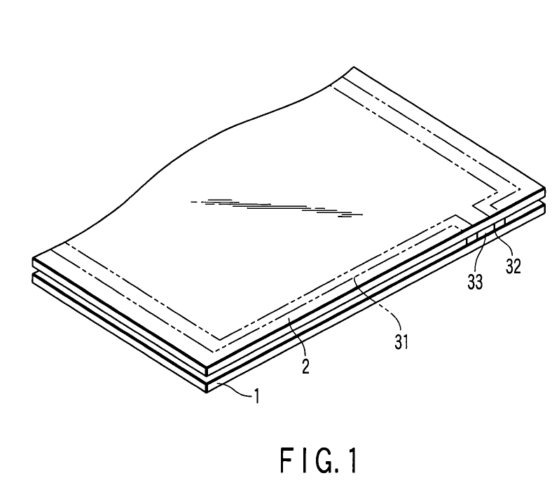

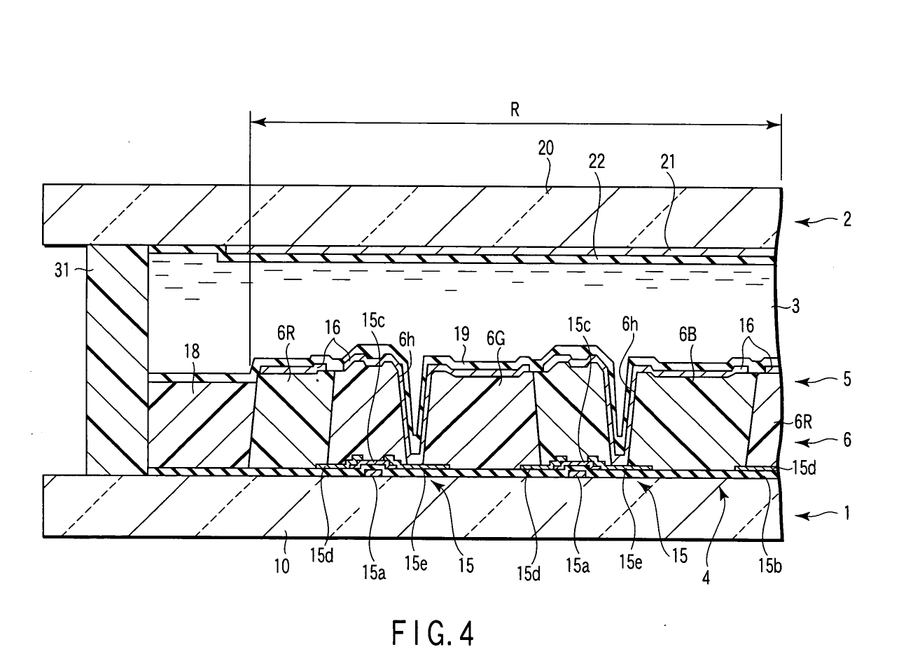

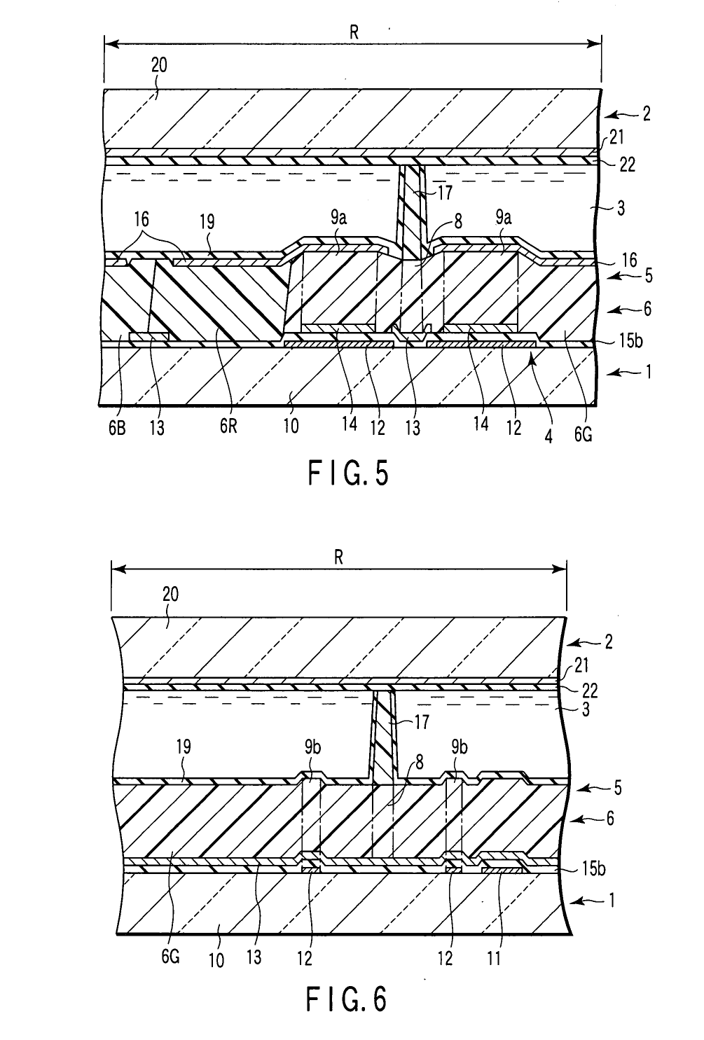

As shown in FIGS. 1 to 6, the liquid crystal display panel comprises an array substrate 1, a counter substrate 2, and a liquid crystal layer 3. The array substrate 1 has a display region R. The counter substrate 2 is arranged opposite to the array substrate 1 and spaced therefrom by a predetermined gap. The liquid crystal layer 3 is interposed between the substrates 1 and 2.

The array substrate 1 comprises a glass substrate 10, an array wiring section 4, an under layer 5, a plurality of pixel electrodes 16, a plurality of pillar-shaped spacers 17, and an alignment film 19. The glass substrate 10 is a transparent substrate. The array wiring section 4 is formed on the glass substrate 10. The under layer 5 is formed on the glass substrate and the array wiring section. The pixel electrodes 16 and the pillar-shaped spacers 17 are formed on the under layer 5. The alignment film 19 is formed on the under layer and the pixel electrodes.

The array wiring section 4 has a plurality of scanning lines 11, a plurality of signal lines 13, and a plurality of thin-film transistors (TFTs) 15. The TFTs 15 are used as switching elements. The under layer 5 has a plurality of red color layers 6R, a plurality of green color layers 6G, and a plurality of blue color layers 6B. The color layers 6R, 6G and GB constitute a color filter 6.

The scanning lines 11 and the signal lines 13 are arranged on the glass substrate 10, forming a lattice. The scanning lines 11 extend in the first direction d1 that is parallel to the plane of the glass substrate 10. The signal lines 13 extend in the second direction d2 that is parallel to the plane of the glass substrate 10 and intersecting at right angles with the first direction d1. The scanning lines 11 are 0.35 μm thick, and the signal lines 13 are 0.55 μm thick. The TFTs 15 are provided near the intersections of the scanning lines 11 and signal lines 13.

Each TFT 15 has a gate electrode 15a, a gate insulating film 15b, a semiconductor film 15c, a source electrode 15d, and a drain electrode 15e. The gate electrode 15a is a projecting part of a scanning line 11. The gate insulating film 15b is provided on the gate electrode 15a. The semiconductor film 15c is opposed to the gate electrode 15a across the gate-insulting film 15b. The source electrode 15d is connected to the source region of the semiconductor film 15c. The drain electrode 15e is connected to the drain region of the semiconductor film 15c. The source electrode 15d is connected to a signal line 13. The drain electrode 15e is connected to a pixel electrode 16.

In the display region R, the color layers 6R, 6G and 6B are provided adjacent to one another, on the glass substrate 10, scanning lines 11, signal lines 13 and TFTs 15 and are alternately arranged. The color layers 6R, 6G and 6B are shaped like stripes and arranged, each having lateral edges aligned with two adjacent signal lines 13. In this embodiment, the color layers 6R, 7G and 6B are 3.0 μm thick.

The under layer 5 includes a plurality of base parts 8 and a plurality of protective parts 9. The base parts 8 are bases for the pillar-shaped spacers 17. The protective parts 9 are located near the base parts 8, respectively, and have a height greater than that of the base parts. The surface of each base part 8 is parallel to, and flush with, the plane of the glass substrate 10.

The pixel electrodes 16 are made of transparent conductive material such as indium-tin oxide (ITO) and formed on the color layers 6R, 6G and 6B. Each pixel electrode 16 extends through a contact hole made in one color layer and is electrically connected to the drain electrode 15e of the corresponding TFT 15. The pillar-shaped spacers 17 are formed on the base parts 8 of the under layer 5, respectively. The alignment film 19 is formed on the under layer 5 on which the pixel electrodes 16 and pillar-shaped spacers 17 are formed.

Outside the display region R, a light-shielding member 18 shaped like a frame is formed on the glass substrate 10. The light-shielding member 18 surrounds all color layers provided in the display region R. The shielding member 18 shields the light leaking at the edges of the display region R. Note that the alignment film 19 covers not only the display region R, but also the other part of the glass substrate 10, i.e., the region outside the display region R.

The counter substrate 2 comprises a glass substrate 20 that is a transparent insulating substrate. On this glass substrate 20, a counter electrode 21 is formed. The counter electrode 21 is made of transparent conductive material such as ITO. In the display region R, an alignment film 22 is formed on the counter electrode 21. The alignment film 22 is formed not only in the display region R. Rather, it is formed on the entire surface of the glass substrate 20.

The array substrate 1 and the counter substrate 2 are arranged opposite to each other with a predetermined gap therebetween by the pillar-shaped spacers 17. The array substrate 1 and counter substrate 2 are bonded to each other with a sealing member 31 provided at the edge portions of both substrates. The sealing member 31 is arranged along the outer periphery of the light-shielding member 18. The liquid crystal layer 3 is interposed between the array substrate 1 and the counter substrate 2. The sealing member 31 has a liquid-crystal port 32, which is closed with a sealant 33.

A method of manufacturing the array substrate 1 and liquid crystal display panel, which are configured as described above, will be explained in detail.

### Embodiment 1

First, the configuration of the array substrate 1 will be described.

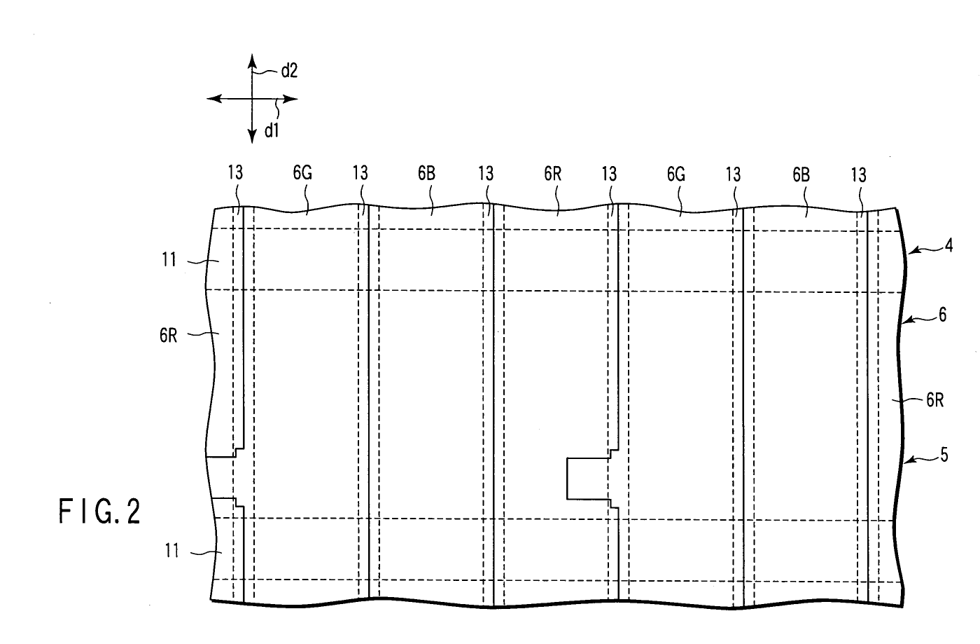

As FIGS. 2, 3, 5, 6 and 7 show, the array substrate according to Embodiment 1 further comprises a plurality of dummy scanning lines 12 and a plurality of dummy signal lines 14. The under layer 5 is constituted by color layers 6R, 6G and 6G. Of these color layers, the color layers 6G include a base part 8 and a protective part 9 each.

The base part 8 overlaps one signal line 13. The protective part 9 is composed of first protective portions 9a and second protective portions 9b. The first protective portions 9a are spaced apart in the first direction d1 and opposed to each other across the base part 8. The second protective portions 9b are spaced apart in the second direction d2 and opposed to each other across the base part 8. The first protective portions 9a overlap one dummy scanning line 12 and one dummy signal line 14, respectively. Similarly, the second protective portions 9b overlap one dummy scanning line 12 and one signal line 13, respectively. Hence, the protective part 9 consists of four portions that are arranged at the four sides of one base part 8.

A method of manufacturing the liquid crystal display panel will be described.

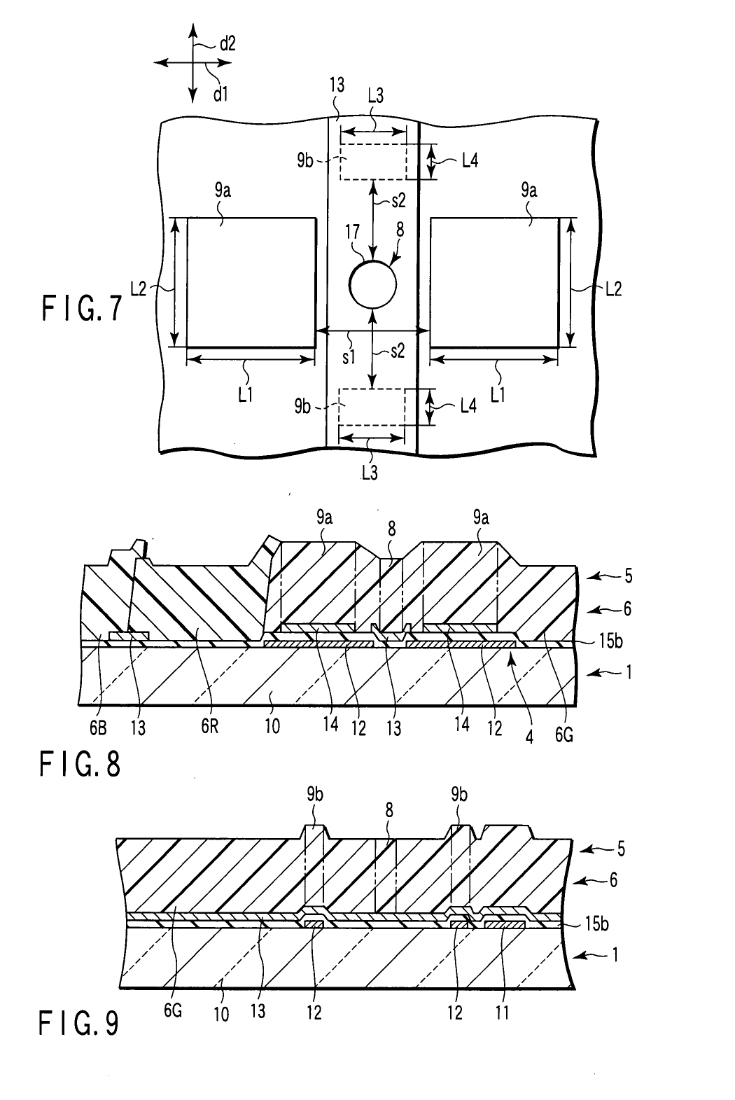

A glass substrate 10 is prepared as FIGS. 2, 3, 7, 8 and 9 show. Ordinary manufacturing steps, such as film forming and patterning, are performed, thereby forming scanning lines 11, dummy scanning lines 12, signal lines 13, dummy signal lines 14 and TFTs 15 including a gate insulating film 15a. The scanning lines 11 and dummy scanning lines 12 are formed on the glass substrate 10 at the same time, by using the same material. The scanning lines 11 and the dummy scanning lines 12 are 0.35 μm thick. The signal lines 13 and dummy signal lines 14 are formed on the gate insulting film 15b at the same time by using the same material, and overlap the dummy scanning lines 12. The signal lines 13 and dummy signal lines 14 are 0.55 μm thick.

Subsequently, a photosensitive green resist (hereinafter called green resist) having green pigment dispersed in it and used as an organic pigment is applied to the glass substrate 10. Thereafter, the green resist is exposed to light through a photomask and then developed and baked. Green layers 6G are thereby formed in the display region R. At the same time, contact holes 6h are made in the color layers 6G. Next, red layers 6R and blue layers 6B are formed in the display region R in the same way as the color layers 6G, and located adjacent the cooler layers 6G, respectively. Contact holes 6h are made in the red layers 6R and blue layers 6B, too. The color layers 6R, 6G and 6B are 3.0 μm thick.

As indicated above, color layers 6G include base parts 8, first protective portions 9a, and second protective portions 9b. The surface of the base part 8 is parallel to, and flush with, the plane of the glass substrate 10. The first protective portions 9a and second protective portions 9b have a height 0.35 μm greater than that of the base part 8. The first protective portions 9a are rectangular, having length L1 of 50 μm in the first direction d1 and length L2 of 50 μm in the second direction d2. The first protective portions 9a face each other across the base part 8, are spaced apart by distance s1 of 60 μm and provided outside the base part 8. The second protective portions 9b are rectangular, having length L3 of 20 μm in the first direction d1 and length L4 of 10 μm in the second direction d2. The second protective portions 9b face each other across the base part 8, are spaced apart by distance s2 of 40 μm and provided outside the base part 8.

The order in which the color layers 6R, 6G and 6B are formed is not limited to the order adopted in this embodiment. The color layers can be formed in any other order. The exposure apparatus used to perform photolithography is preferably a proximity exposure apparatus from the viewpoint of productivity. A mirror-projection exposure apparatus may be used instead, in order to increase the patterning precision and reduce the height difference between the stepped parts. The exposure apparatus employed in the present embodiment is a mirror-projection exposure apparatus.

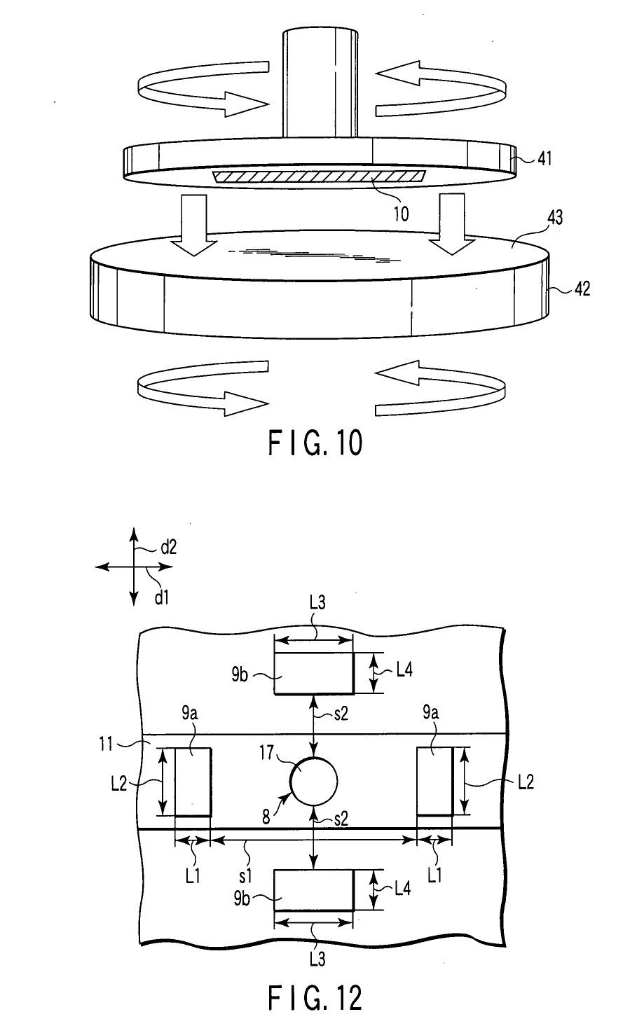

Next, as shown in FIG. 10, the glass substrate 10 is attached by suction to the polishing head 41 of a polishing apparatus. Then, the stage 42 of the polishing apparatus is positioned such that the polishing surface 43 of the stage 42 faces the color layers 6R, 6G and 6B. This done, the polishing head 41 and the stage 42 are rotated in the opposite directions, and the polishing agent is applied. The color layers 6R, 6G and 6B are thereby mechanically polished at their surfaces. Thus, the color layers 6R, 6G and 6B attain flat surfaces. Since the protective parts 9 are provided near the base parts 8, the polishing rate (i.e., polishing speed) of the base parts can be much lowered. This can greatly reduce the height difference between the base parts. The base parts 8 thus polished have surfaces that are parallel to, and flush with, the plane of the glass substrate 10.

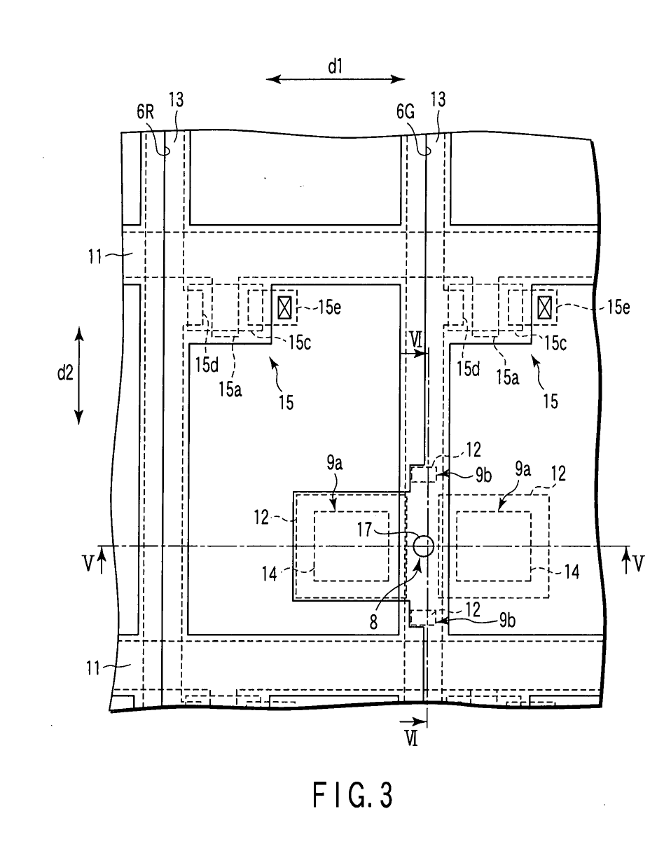

As FIGS. 3, 4, 6 and 7 show, ITO is deposited on the color layers 6R, 6G and 6B by means of, for example, sputtering. Then, photolithography is performed on the ITO layer deposited. The ITO layer is thereby patterned, forming a plurality of pixel electrodes 16. The pixel electrodes 16 overlap the color layers, respectively, and extend through the contact holes 6h.

After the pixel electrodes 16 have been formed, a spinner applies photosensitive black resist (hereinafter called black resist), i.e., material that can shield light, to the glass substrate 10. The black resist is dried. The black resist dried is patterned, developed and baked. The light-shielding member 18 is thereby formed.

Next, the glass substrate 10 is coated with a resist. The resist is exposed to light. The resist is developed and baked (or post-baked). A plurality of pillar-shaped spacers 17 are thereby formed on the base parts 8. The pillar-shaped spacers 17 therefore have the same height as measured from the surface of the glass substrate 10. An array substrate 1 can therefore be obtained, in which the difference between the spacers is small in terms of height.

Then, an alignment film 19 is formed on the entire surface of the glass substrate 10, which includes the display region R. Rubbing is performed on the alignment film 19. The manufacture of the array substrate 1 is thereby completed.

In a method of manufacturing the counter substrate 2, a glass substrate 20 is first prepared. On the glass substrate 20, ITO is deposited by means of, for example, sputtering. A counter electrode 21 is thereby formed. Subsequently, an alignment film 22 is formed on the entire surface of the glass substrate 20, including the display region R. Rubbing performed on the alignment film in a specific direction. The counter substrate 2 is thereby manufactured.

Next, a sealing member 31 of, for example, thermosetting type is printed on the edges of the glass substrate 20. Then, the array substrate 1 and the counter substrate 2 are arranged opposite to each other with a predetermined gap therebetween by the pillar-shaped spacers 17. The edges of the array substrate are bonded to those of the counter substrate, using the sealing member 31. Thereafter, the sealing member 31 is heated and thereby cured. Thus, the array substrate 1 and the counter substrate 2 are secured to each other.

Subsequently, liquid crystal is poured into the space between the substrates 1 and 2, by vacuum injection, through the liquid-crystal port 32 made in the sealing member 31. Then, the liquid-crystal port 32 is closed with the sealant 33, which is made of resin that can be cured with ultraviolet rays. A liquid crystal layer 3 is thereby formed. A liquid crystal display panel is thus provided, which has a uniform cell gap. The cell gap may be changed in accordance with the specification of the liquid crystal display panel. To change the cell gap, it suffices to change the height measured from the plane of the color layers to the surface of the base parts 8 and to change the height of the pillar-shaped spacers 17.

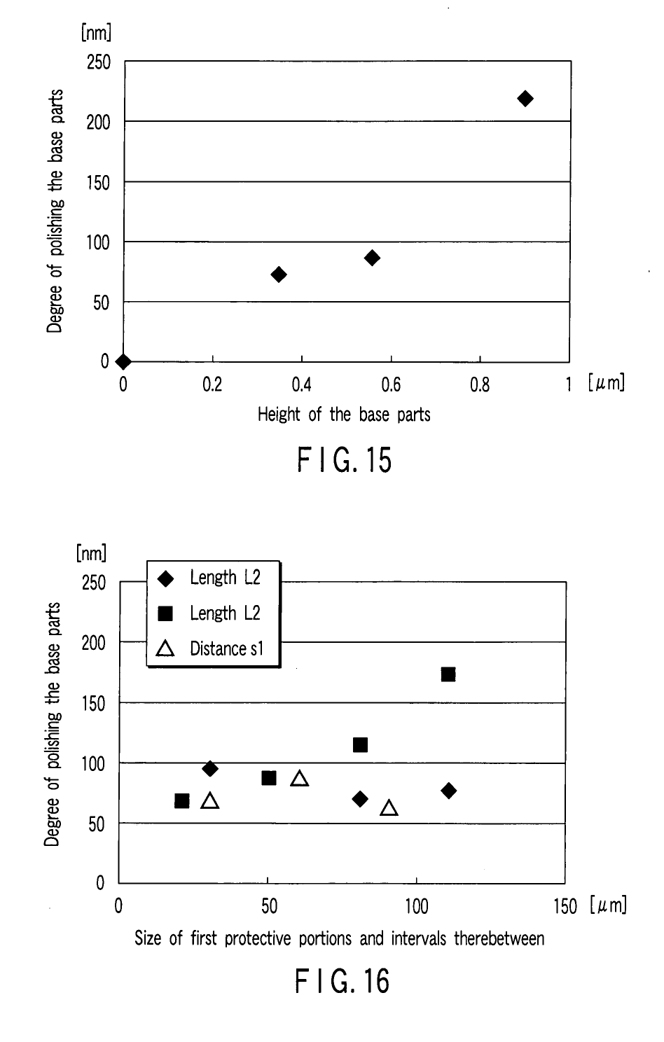

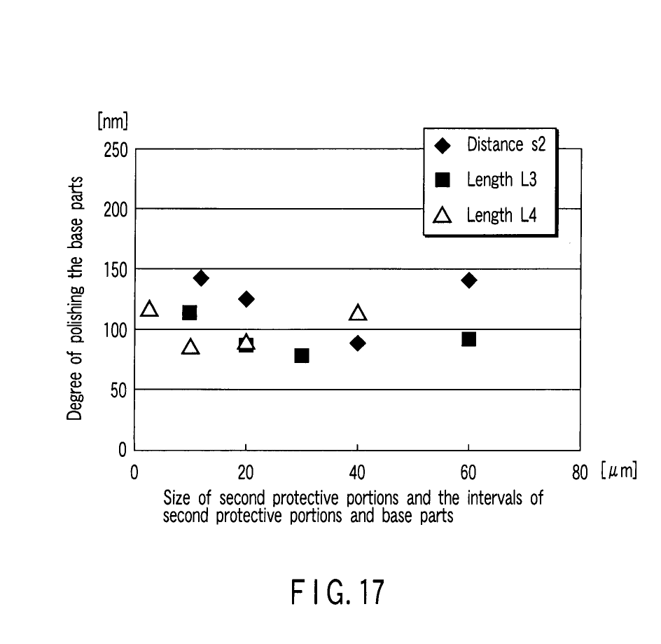

The inventors thereof measured the height of the base parts 8 by using a stylus thickness meter, both before polishing the parts 8 and after polishing the parts 8, and calculated how much the base parts 8 had been polished. As seen from FIGS. 15, 16 and 17, the base parts 8 had been polished by 88 nm. Thus, the rate at which the base parts 8 are polished was greatly decreased. As a result, the difference between the base parts was much reduced in terms of height.

### Embodiment 2

In Embodiment 2, the array substrate 1 had no first protective portions 9a. Neither dummy scanning lines nor dummy signal lines were formed, because the dummy scanning lines 12 and dummy signal lines 14 constitute the first protective portions 9a in Embodiment 1. In any other respect, the array substrate 1 was identical to that of Embodiment 1. Using the array substrate 1, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 152 nm. Thus, the rate of polishing the base parts 8 was greatly decreased. As a result, the difference between the base parts was much reduced in terms of height.

### Embodiment 3

In Embodiment 3, the first protective portions 9a had length L2 of 10 μm. That is, length L2 was changed from 50 μm to 10 μm. Except for this point, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 150 nm. Thus, the rate of polishing the base parts 8 was greatly decreased. As a result, the difference between the base parts was much reduced in terms of height.

### Embodiment 4

In Embodiment 4, the first protective portions 9a had length L2 of 80 μm. That is, length L2 was changed from 50 μm to 80 μm. Except for this point, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 72 nm. Thus, the rate of polishing the base parts 8 was greatly decreased. As a result, the difference between the base parts was much reduced in terms of height.

### Embodiment 5

In Embodiment 5, the first protective portions 9a had length L2 of 110 μm. That is, length L2 was changed from 50 μm to 110 μm. Except for this point, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 78 nm. Thus, the rate of polishing the base parts 8 was greatly decreased. As a result, the difference between the base parts was much reduced in terms of height.

### Embodiment 6

In Embodiment 6, the first protective portions 9a had length L1 of 20 μm. That is, length L1 was changed from 50 μm to 20 μm. Except for this point, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 69 nm. Thus, the rate of polishing the base parts 8 was greatly decreased. As a result, the difference between the base parts was much reduced in terms of height.

### Embodiment 7

In Embodiment 7, the first protective portions 9a had length L1 of 80 μm. That is, length L1 was changed from 50 μm to 80 μm. Except for this point, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 115 nm. Thus, the rate of polishing the base parts 8 was greatly decreased. As a result, the difference between the base parts was much reduced in terms of height.

### Embodiment 8

In Embodiment 8, the first protective portions 9a had length L1 of 110 μm. That is, length L1 was changed from 50 μm (in Embodiment 1) to 110 μm. Except for this point, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 158 nm. Thus, the rate of polishing the base parts 8 was greatly decreased. As a result, the difference between the base parts was much reduced in terms of height.

### Embodiment 9

In Embodiment 9, the first protective portions 9a were formed outside the base parts 8, opposed to the base parts 8 in the first direction d1 and arranged at intervals of 30 μm. Thus, distance s1 was changed from 60 μm to 30 μm. Except for this point, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 70 nm. Thus, the rate of polishing the base parts 8 was greatly decreased. As a result, the difference between the base parts was much reduced in terms of height.

### Embodiment 10

In Embodiment 10, the first protective portions 9a were formed outside the base parts 8, opposed to the base parts 8 in the first direction d1 and arranged at intervals of 100 μm. Thus, distance s1 was changed from 60 μm to 100 μm. Except for this point, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 65 nm. Thus, the rate of polishing the base parts 8 was greatly decreased. As a result, the difference between the base parts was much reduced in terms of height.

### Embodiment 11

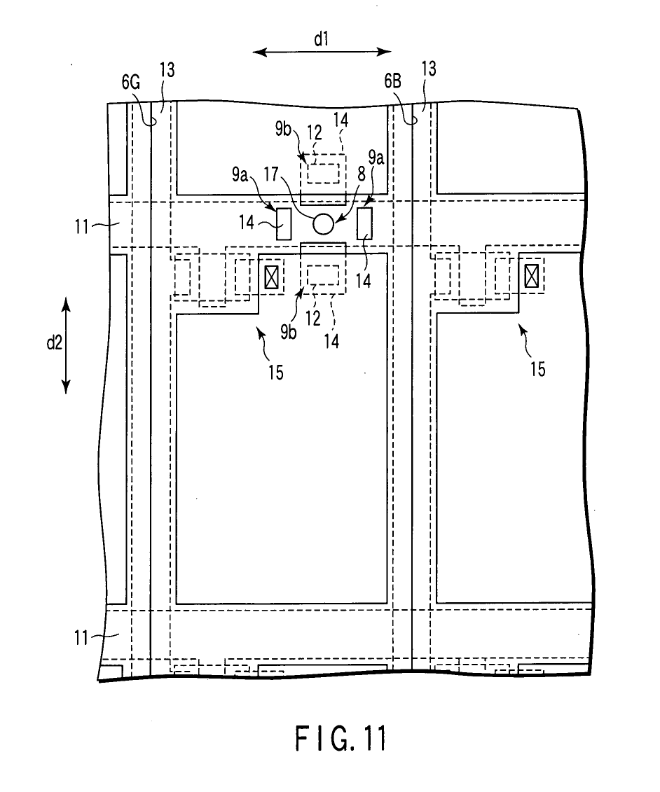

As shown in FIGS. 11 and 12, the base parts 8 overlap the scanning lines 11. The first protective portions 9a overlap the scanning lines 11 and dummy signal lines 14. The second protective portions 9b overlap the dummy scanning lines 12 and dummy signal lines 14. The signal lines 13 are formed outside the dummy scanning lines 12 and on the gate insulating film 15b. The dummy signal lines 14 are formed on the gate insulating film 15b, overlapping the scanning lines 11 and the dummy scanning lines 12. The first protective portions 9a and the second protective portions 9b have a height 0.55 μm greater than that of the base parts 8. Except that the base parts 8, the first protective portions 9a and the second protective portions 9b are formed on the color layers 6G, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 170 nm. Thus, the rate of polishing the base parts 8 was greatly decreased. As a result, the difference between the base parts was much reduced in terms of height.

### Embodiment 12

In Embodiment 12, the array substrate 1 has no second protective portions 9b. That is, neither dummy scanning lines 12 nor dummy signal lines 14 were formed. In any other respect, the array substrate 1 was identical to that of Embodiment 11. Using the array substrate 1, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 135 nm. Thus, the rate of polishing the base parts 8 was greatly decreased. As a result, the difference between the base parts was much reduced in terms of height.

### Embodiment 13

In Embodiment 13, the second protective portions 9b were formed outside the base parts 8, opposed to the base parts 8 in the second direction d2 and spaced apart by distance s2 of 10 μm. Thus, distance s2 was changed from 40 μm to 10 μm. Except for this point, an array substrate was manufactured in the same way as in Embodiment 11. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 150 nm. Thus, the rate of polishing the base parts 8 was greatly decreased. As a result, the difference between the base parts was much reduced in terms of height.

### Embodiment 14

In Embodiment 14, the second protective portions 9b were formed outside the base parts 8, opposed to the base parts 8 in the second direction d2 and spaced apart by distance s2 of 20 μm. Thus, distance s2 was changed from 40 μm to 20 μm. Except for this point, an array substrate was manufactured in the same way as in Embodiment 11. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 127 nm. Thus, the rate of polishing the base parts 8 was greatly decreased. As a result, the difference between the base parts was much reduced in terms of height.

### Embodiment 15

In Embodiment 15, the second protective portions 9b were formed outside the base parts 8, opposed to the base parts 8 in the second direction d2 and spaced by distance s2 of 70 μm. Thus, distance s2 was changed from 40 μm to 70 μm. Except for this point, an array substrate was manufactured in the same way as in Embodiment 11. Using this array substrate, a liquid crystal display panel was manufactured.

The inventors hereof measured the height of the base parts 8 by using the stylus thickness meter, both before polishing the parts 8 and after polishing the parts. 8, and calculated how much the base parts 8 had been polished. It was found that the base parts 8 had been polished by 170 nm. Thus, the rate of polishing the base parts 8 was greatly decreased. As a result, the difference between the base parts was much reduced in terms of height.

### Embodiment 16

In Embodiment 16, the second protective portions 9b had length L3 of 10 μm. That is, length L3 was changed from 20 μm to 10 μm. Except for this point, an array substrate was manufactured in the same way as in Embodiment 11. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 113 nm. Thus, the rate of polishing the base parts 8 was greatly decreased. As a result, the difference between the base parts was much reduced in terms of height.

### Embodiment 17

In Embodiment 17, the second portions 9b had length L3 of 30 μm. That is, length L3 was changed from 20 μm to 30 μm. Except for this point, an array substrate was manufactured in the same way as in Embodiment 11. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 78 nm. Thus, the rate of polishing the base parts 8 was greatly decreased. As a result, the difference between the base parts was much reduced in terms of height.

### Embodiment 18

In Embodiment 18, the second protective portions 9b had length L3 of 60 μm. That is, length L3 was changed from 20 μm to 60 μm. Except for this point, an array substrate was manufactured in the same way as in Embodiment 11. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 92 nm. Thus, the rate of polishing the base parts 8 was greatly decreased. As a result, the difference between the base parts was much reduced in terms of height.

### Embodiment 19

In Embodiment 19, the second protective portions 9b had length L4 of 5 μm. That is, length L4 was changed from 10 μm to 5 μm. Except for this point, an array substrate was manufactured in the same way as in Embodiment 11. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 119 nm. Thus, the rate of polishing the base parts 8 was greatly decreased. As a result, the difference between the base parts was much reduced in terms of height.

### Embodiment 20

In Embodiment 20, the second protective portions 9b had length L4 of 20 μm. That is, length L4 was changed from 10 μm to 20 μm. Except for this point, an array substrate was manufactured in the same way as in Embodiment 11. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 93 nm. Thus, the rate of polishing the base parts 8 was greatly decreased. As a result, the difference between the base parts was much reduced in terms of height.

### Embodiment 21

In Embodiment 21, the second protective portions 9b had length L4 of 40 μm. That is, length L4 was changed from 10 μm to 40 μm. Except for this point, an array substrate was manufactured in the same way as in Embodiment 11. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 114 nm. Thus, the rate of polishing the base parts 8 was greatly decreased. As a result, the difference between the base parts was much reduced in terms of height.

### Embodiment 22

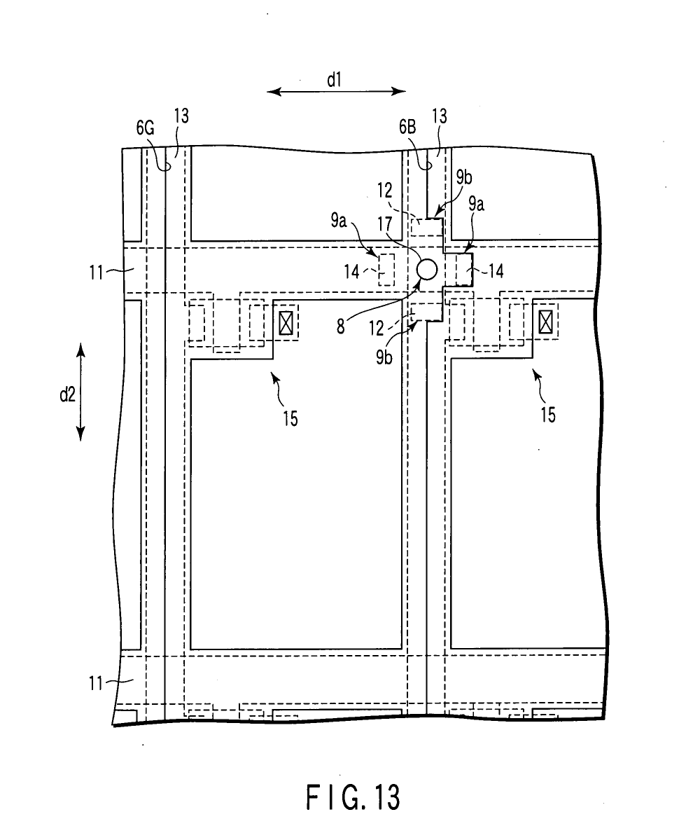

In Embodiment 22d, the base parts 8 overlap the scanning lines 11 and signal lines 13 as shown in FIG. 13. Therefore, the first protective parts 8 overlap the intersections of the scanning lines 11 and the signals lines 13. The first protective portions 9a overlap the scanning lines 11 and dummy signal lines 14. The second protective portions 9b overlap the dummy scanning lines 12 and signal lines 13.

The signal lines 13 are formed on the gate insulating film 15b, overlapping the scanning lines 11 and the dummy scanning lines 12. The dummy signal lines 14 are formed on the gate insulating film 15b, overlapping the scanning lines 11. The first protective portions 9a and the second protective portions 9b have a height as large as that of the base parts 8. Except that the base parts 8, first protective portions 9a and second protective parts 9b are formed on the color layers 6G, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 220 nm. Thus, the rate of polishing the base parts 8 was greatly decreased. As a result, the difference between the base parts was much reduced in terms of height.

### Embodiment 23

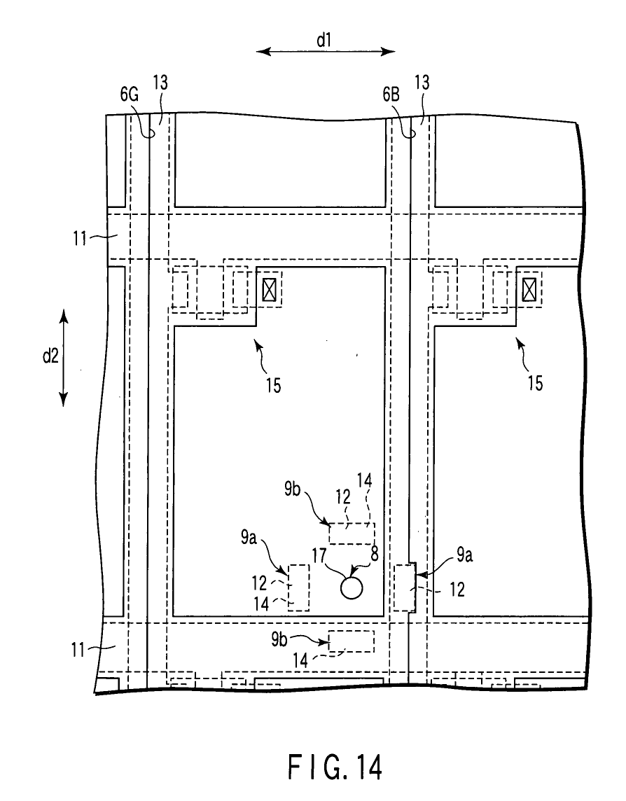

As shown in FIG. 14, the base parts 8 are formed in a region outside the overlap the scanning lines 11 and signal lines 13. That is, the base parts 8 are provided in a non-overlapping region, outside the array wiring section 4. The first protective portions 9a overlap the dummy scanning lines 12 and signal lines 13 or the dummy scanning 12 and dummy signal lines 14. The second protective parts 9b overlap the scanning lines 11 and dummy signal lines 14 or the dummy scanning lines 12 and dummy signal lines 14.

The signal lines 13 are formed on the gate insulating film 15b, overlapping the scanning lines 11 and some of the dummy scanning line 12. The dummy signal lines 14 are formed on the gate insulating film 15b, overlapping either the scanning lines 11 or the dummy scanning lines 12. The first protective portions 9a and the second protective portions 9b have a height 0.90 μm greater than that of the base parts 8. Except that the base parts 8, first protective portions 9a and second protective portions 9b are formed on the color layers 6G, an array substrate was manufactured in the same way as in Embodiment 1. Using this array substrate, a liquid crystal display panel was manufactured.

The inventors hereof measured the height of the base parts 8 by using the stylus thickness meter, both before polishing the parts 8 and after polishing the parts 8, and calculated how much the base parts 8 had been polished. It was found that the base parts 8 had been polished by 0 nm. Thus, the rate of polishing the base parts 8 was greatly decreased. As a result, the height difference between the base parts was much reduced.

As described above, the readiness with the color layers 6R, 6G and 6B are polished will be explained.

The rate at which the above-mentioned polishing apparatus polishes the color layers that lie at the lowest level in the substrate surface is 0.5 nm/sec to 3 nm/sec. The color layers are provided at the position where pillar-shaped spacers are formed in the conventional display panels. The color layers, which lie at the highest level in the substrate surface, are polished at a very high rate ranging from 5 nm/sec to 12 nm/sec. This is why the polishing rate causes changes in the cell gap the conventional display panels.

In the embodiments described above, the rate at with the base parts 8 are polished can be greatly decreased to 3 nm/sec to 5 nm/sec, because the protective parts 9 that are 0.3±0.1 μm high are provided near the base parts 8. This minimizes the height difference between the base parts 8.

In the liquid crystal display panel so configured as described above and in the method of manufacturing this liquid crystal display panel, a plurality of base parts 8 and a plurality of protective parts 9 are formed on the color layers 6G. Hence, the protective parts 9 protect the base parts 8 against polishing even if the color layers 6R, 6G and 6B are mechanically polished. The base parts 8 can have surfaces almost flush with one another after the color layers have been formed, which include a base part 8 each. Since the height difference between the base parts 8 is greatly reduced, the liquid crystal display panel can have a uniform cell gap. For example, a liquid crystal display panel of OCB mode can acquire good display characteristics though its display characteristics are much influenced by the cell gap, because the height difference between the base parts 8 can be 0.20 μm or less.

As can be understood from Embodiments 1 to 23, the degree to which the base parts 8 are polished can be decreased if the first protective portions 9a and second protective portions 9b are formed under any one of the following conditions, provided that length L1=50 μm, length L2=50 μm, distance s1=60 μm, length L3=20 μm, length L4=10 μm and distance s2=40 μm, each being a reference value.

(1) The first protective portions 9a are rectangular and have length L1 of 110 μm or less.

(2) The first protective portions 9a are rectangular and have length L2 of 10 μm or more.

(3) The first protective portions 9a face each other across the base part 8, are spaced apart by distance s1 of 10 μm to 70 μm.

(4) The second protective portions 9b are rectangular and have length L3 of 10 μm to 60 μm.

(5) The second protective portions 9b are rectangular and have length L4 of 5 μm to 40 μm.

(6) The second protective portions 9b are formed outside the base parts 8 and spaced apart by distance s2 of 10 μm to 70 μm.

The first protective portions 9a and the second protective portions 9b may be formed under any possible combination of the conditions (1) to (6) described above. In this case, too, the same advantages as specified above can be attained.

As has been described, the present invention can provide an array substrate that helps to provide a liquid crystal display panel able to display high-quality images and a method of manufacturing this array substrate.

The present invention is not limited to the embodiments described above. The components of any embodiment can be modified in various manners in reducing the invention to practice, without departing from the sprit or scope of the invention. Further, the components of any embodiment described above may be combined, if necessary, in various ways to make different inventions. For example, some of the component of any embodiment may not be used. Moreover, the components of the different embodiments may be combined in any desired fashion.

The protective parts 9 may be formed near the base parts 8, overlapping either scanning lines 11 or the dummy scanning lines 12, and either the signal lines 13 or the dummy signal lines 14. The number and shape of the protective parts 9 formed near each base part 8 are not limited to those in the embodiments described above. For example, one protective part 9 shaped like letter L, letter U or a rectangular frame may be formed. In this case, too, the advantages described above can be achieved.

The color layers, on which the base parts 8 and the protective parts 9 are formed, are not limited to the color layers 6G. The base parts 8 and the protective parts 9 may be formed on the color layers 6R or 6B, or on layers of different colors. In any one of these cases, the advantages described above can be attained. The under layer 5 can include the base pats 8 and the protective parts 9, in addition to the color layers 6R, 6G and 6B. In this case, too, the above-mentioned advantages can be achieved. For example, the color layers 6R, 6G and 6B may be laid one upon another, thus forming the under layer 5. If this is the case, the base parts 8 may be provided in recesses made in an insulting layer. The protective parts 9 may be provided in projections made in an insulating layer.

The array wiring section 4 may have a plurality of auxiliary capacitance lines. At the same time the auxiliary capacitance lines are formed, a plurality of dummy auxiliary capacitance lines may be formed, using the same material. In this case, the under layer 5 may include the base parts 8 or protective parts 9 which overlap the auxiliary capacitance lines.

What is claimed is:

1. A method of manufacturing an array substrate, comprising:
forming a plurality of scanning lines, a plurality of signal lines and a plurality of switching elements on a substrate;
forming an under layer having a plurality of color layers overlapping the scanning lines, the signal lines and the switching elements, a plurality of base parts, and a plurality of protective parts located near the base parts and having a height equal to or greater than that of the base parts;
polishing a surface of the under layer; and
forming a plurality of pillar-shaped spacers on the base parts after the surface of the under layer has been polished.

2. A method of manufacturing an array substrate, comprising:
forming a plurality of scanning lines, a plurality of signal lines and a plurality of switching elements on a substrate;
forming an under layer having a plurality of color layers overlapping the scanning lines, the signal lines and the switching elements, a plurality of base parts located in a plane which is parallel to a surface of the substrate, and a plurality of protective parts located near the base parts and having a height equal to or greater than that of the base parts;
polishing a surface of the under layer; and
forming a plurality of pillar-shaped spacers on the base parts after the surface of the under layer has been polished.

3. The method according to claim 1, wherein a plurality of dummy scanning lines made of the same material as the scanning lines are formed on the substrate at the same time as the scanning lines; the signal lines are formed, overlapping the dummy scanning lines; and the under layer is formed, which includes the base parts which overlap the signal lines and a plurality of protective parts which overlap the dummy scanning lines and signal lines.

4. The method according to claim 2, wherein a plurality of dummy scanning lines made of the same material as the scanning lines are formed on the substrate at the same time as the scanning lines; the signal lines are formed, overlapping the dummy scanning lines; and the under layer is formed, which includes the base parts which overlap the signal lines and a plurality of protective parts which overlap the dummy scanning lines and signal lines.

5. The method according to claim 3, wherein a plurality of dummy signal lines made of the same material as the signal lines are formed on the substrate at the same time as the signal lines, overlapping the dummy scanning lines; and the under layer is formed, which includes the protective parts overlapping the dummy scanning lines and dummy signal lines.

6. The method according to claim 4, wherein a plurality of dummy signal lines made of the same material as the signal lines are formed on the substrate at the same time as the signal lines overlapping the dummy scanning lines; and the under layer is formed, which includes the protective parts overlapping the dummy scanning lines and dummy signal lines.

7. The method according to claim 1, wherein a plurality of dummy signal lines made of the same material as the signal lines are formed on the substrate at the same time as the signal lines, overlapping the scanning lines; and the under layer is formed, which includes the base parts overlapping the scanning lines and the protective parts overlapping the scanning lines and dummy signal lines.

8. The method according to claim 7, wherein a plurality o dummy scanning lines made of the same material as the scanning lines are formed on the substrate at the same time as the scanning lines,; the dummy signal lines are formed, overlapping the dummy scanning lines; and the under layer is formed, which includes the protective parts overlapping the dummy scanning lines and dummy signal lines.

9. The method according to claim 1, wherein a plurality of dummy scanning lines made of the same material as the scanning lines are formed on the substrate at the same time as the scanning lines; the signal lines are formed, overlapping the dummy scanning lines; a plurality of dummy signal lines are formed on the substrate at the same time as the signal lines, said dummy signal lines being made of the same material as the signal lines and overlapping the scanning lines; and the under layer is formed, which includes the base parts overlapping the scanning lines and signal lines and the protective parts overlapping the scanning lines and dummy signal lines, or dummy scanning lines and signal lines.

10. The method according to claim 2, wherein a plurality of dummy scanning lines made of the same material as the scanning lines are formed on the substrate at the same time as the scanning lines; the signal lines are formed, overlapping the dummy scanning lines: a plurality of dummy signal lines are formed on the substrate at the same time as the signal lines, said dummy signal lines being made of the same material as the signal line and overlapping the scanning lines; and the under layer is formed, which includes the base parts overlapping the scanning lines and signal lines and the protective parts overlapping the scanning lines and dummy signal lines, or dummy scanning lines and signal lines.

11. The method according to claim 8, wherein the scanning lines are formed, which extend in a first direction; the signal lines are formed, which extend in a second direction intersecting at right angels with the first direction; and the protective parts are rectangular, have a length of 10 μm to 60 μm measured in the first direction, are provided outside the base parts and face one another across the base parts in the second direction.

12. The method according to claim 9, wherein the scanning lines are formed, which extend in a first direction; the signal lines are formed, which extend in a second direction intersecting at right angels with the first direction; and the protective parts are rectangular, have a length of 10 μm to 60 μm measured in the first direction, are provided outside the base parts and face one another across the base parts in the second direction.

13. The method according to claim 10, wherein the scanning lines are formed, which extend in a first direction; the signal lines are formed, which extend in a second direction intersecting at right angels with the first direction; and the protective parts are rectangular, have a length of 10 μm to 60 μm measured in the first direction, are provided outside the base parts and face one another across the base parts in the second direction.

14. The method according to claim 7, wherein the scanning lines are formed, which extend in a first direction; the signal lines are formed, which extend in a second direction intersecting at right angels with the first direction; and the protective parts are rectangular, have a length of at least 10 μm measured in the second direction, are provided outside the base parts and face one another across the base parts in the first direction.

15. The method according to claim 9, wherein the scanning lines are formed, which extend in a first direction; the signal lines are formed, which extend in a second direction intersecting at right angels with the first direction; and the protective parts are rectangular, have a length of at least 10 μm measured in the second direction, are provided outside the base parts and face one another across the base parts in the first direction.

16. The method according to claim 10, wherein the scanning lines are formed, which extend in a first direction; the signal lines are formed, which extend in a second direction intersecting at right angels with the first direction; and the protective parts are rectangular, have a length of at least 10 μm measured in the second direction, are provided outside the base parts and face one another across the base parts in the first direction.

17. The method according to claim 7, wherein the scanning lines are formed, which extend in a first direction; the signal lines are formed, which extend in a second direction intersecting at right angels with the first direction; and the protective parts are rectangular, have a length of at most 110 μm measured in the first direction, are provided outside the base parts and face one another across the base parts in the first direction.

18. The method according to claim 9, wherein the scanning lines are formed, which extend in a first direction; the signal lines are formed, which extend in a second direction intersecting at right angels with the first direction; and the protective parts are rectangular, have a length of at most 110 μm measured in the first direction, are provided outside the base parts and face one another across the base parts in the first direction.

19. The method according to claim 10, wherein the scanning lines are formed, which extend in a first direction; the signal lines are formed, which extend in a second direction intersecting at right angels with the first direction; and the protective parts are rectangular, have a length of at most 110 μm measured in the first direction, are provided outside the base parts and face one another across the base parts in the first direction.

20. An array substrate comprising:
a plurality of scanning lines, a plurality of signal lines and a plurality of switching elements which are formed on a substrate;
an under layer which has a plurality of color layers overlapping the scanning lines, the signal lines and the switching elements, a plurality of base parts, and a plurality of protective parts located near the base parts and having a height equal to or greater than that of the base parts; and
a plurality of pillar-shaped spacers formed on the base parts.
